(19) United States
(12) Patent Application Publication
(10) Pub. No.: US 2026/0047163 A1
(43) Pub. Date: Feb. 12, 2026

(54) SEMICONDUCTOR DEVICE AND A METHOD OF MANUFACTURING THE SAME

(71) Applicant: SK hynix Inc., Gyeonggi-do (KR)

(72) Inventors: Eun Sung LEE, Gyeonggi-do (KR); Myung Dong KO, Gyeonggi-do (KR)

(21) Appl. No.: 19/073,004

(22) Filed: Mar. 7, 2025

(30) Foreign Application Priority Data
Aug. 6, 2024 (KR) 10-2024-0104648

(51) Int. Cl. H10D 62/60; H10D 62/10; H10D 64/01; H10D 64/23; H10D 64/27; H10D 64/66

(52) U.S. Cl. CPC H10D 62/60; H10D 62/102; H10D 64/256; H10D 64/513; H10D 64/667; H10D 64/021

(57) ABSTRACT

A semiconductor device includes a gate structure over a substrate; a source/drain structure in the substrate; and a contact structure over the source/drain region. The source/drain structure includes a first dopant doped region having first dopants doped with a first doping concentration in the substrate; a second dopant doped region having second dopants doped with a second doping concentration under the first dopant doped region in the substrate; and a third dopant doped region protruding from the substrate and having third dopants doped with a third doping concentration. The first dopant concentration is higher than the second dopant concentration. The third dopant concentration is higher than the first dopant concentration.

### CROSS-REFERENCE TO RELATED APPLICATIONS

The present application claims priority under 35 U.S.C. 119 (a) to Korean Patent Application No. 10-2024-0104648, filed on Aug. 6, 2024, which is incorporated herein by reference in its entirety.

### BACKGROUND

### 1. Field

The present disclosure relates generally to semiconductor technology and, more particularly, to a semiconductor device having a transistor structure and a method of manufacturing the semiconductor device.

### 2. Description of the Related Art

A need for a semiconductor device having a high-performance transistor structure has emerged. Advanced semiconductor devices with a high-performance transistor structure are needed for several reasons. Advanced transistor structures may offer better control over the flow of current, reducing leakage and power consumption. This leads to more energy-efficient devices. These devices can operate at higher speeds and handle more complex computations, which is crucial for applications like artificial intelligence, data centers, and high-performance computing. As technology advances, there is a constant push to make devices smaller, more compact, and more powerful. Advanced transistor structures allow for further miniaturization while maintaining or even improving performance. Enhanced transistor designs may also improve the reliability and longevity of semiconductor devices, which is essential for consumer electronics, automotive applications, and other critical systems.

### SUMMARY

An embodiment of the present disclosure provides a high performance transistor structure for a semiconductor device having a low contact resistance.

In accordance with another embodiment of the present disclosure, a semiconductor device includes a gate structure over a substrate; a source/drain structure in the substrate; and a contact structure over the source/drain structure. The source/drain structure includes a first dopant doped region having first dopants doped with a first doping concentration in the substrate; a second dopant doped region having second dopants doped with a second doping concentration under the first dopant doped region in the substrate; and a third dopant doped region protruding from the substrate and having third dopants doped with a third doping concentration. The first dopant concentration is higher than the second dopant concentration. The third dopant concentration is higher than the first dopant concentration.

In accordance with another embodiment of the present disclosure, a semiconductor device includes a gate structure over a substrate; a source/drain structure in the substrate; and a contact structure over the source/drain region. The source/drain structure includes a lower concentration dopant doped region including dopants doped with a low concentration formed in the substrate; a meddle concentration dopant doped region including the dopant doped with a middle concentration protruding from a surface of the substrate; and a high concentration dopant doped region including the dopants doped with a high concentration formed within the middle concentration dopant doped region. The high concentration dopant doped region is adjacent to a lower end of the contact structure.

In accordance with another embodiment of the present disclosure, a method of manufacturing a semiconductor device includes defining an active region in a substrate, forming a gate stack over the active region, forming a first spacer on a side surface of the gate stack, forming a first dopant doped region in the active region exposed by the first spacer, forming a second spacer on a side surface of the first spacer, forming a second dopant doped region under the first dopant doped region in the active region exposed by the second spacer, forming a third dopant doped region over the first dopant doped region, forming a third spacer covering an upper surface of the gate stack, an outer side surface of the second spacer, and an upper surface of the third dopant doped region, forming an interlayer insulating layer covering the gate stack and the third spacer, forming a contact hole penetrating the interlayer insulating layer and the third spacer to expose the third dopant doped region, forming a fourth dopant doped region in the third dopant doped region exposed in the contact hole, and forming a contact plug in the contact hole to form a contact structure.

In accordance with another embodiment of the present disclosure, a method of manufacturing a semiconductor device includes defining an active region in the substrate, forming a gate stack over the active region, forming a low concentration dopant doped region in the active region, forming a middle concentration dopant doped region over the active region, forming a high concentration dopant doped region in the middle concentration dopant doped region, and forming a contact structure in contact with the high concentration dopant doped region.

### BRIEF DESCRIPTION OF THE DRAWINGS

FIG. 1A is a longitudinal cross-sectional view schematically illustrating a transistor structure of a semiconductor device according to an embodiment of the present disclosure.

FIG. 1B is a partially enlarged view of area A in FIG. 1A.

FIGS. 2A to 2N are views illustrating a method of forming a transistor structure of a semiconductor device according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. However, those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

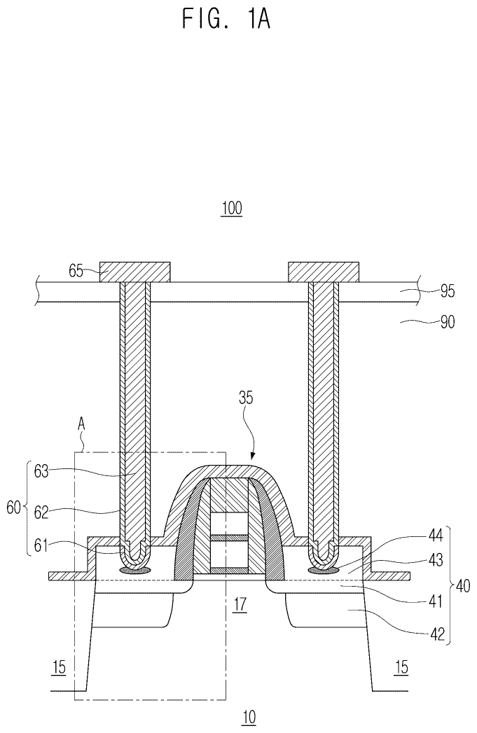

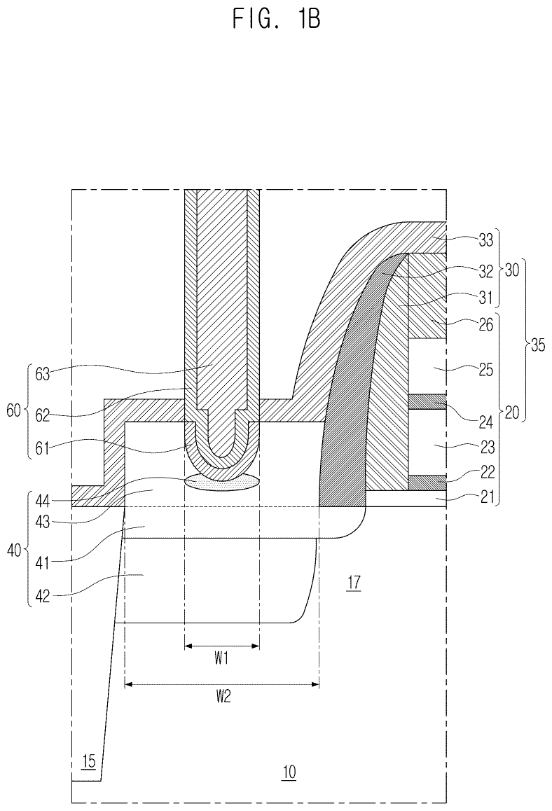

FIG. 1A is a longitudinal cross-sectional view schematically illustrating a transistor structure 100 of a semiconductor device according to an embodiment of the present disclosure, and FIG. 1B is a partially enlarged view of area A in FIG. 1A. Referring to FIG. 1A, the transistor structure 100 of the semiconductor device may include a gate structure 35, source/drain structures 40, and contact structures 60. The gate structure may be formed over the substrate 10. The source drain/structure may be formed in the substrate 10. The contact structures 60 may extend over the substrate 10. The transistor structure 100 may further include isolation regions 15 disposed in the substrate 10. The transistor structure 100 may further include interlayer insulating layers 90 and 95 covering the gate structure 35 and the contact structures 60. The transistor structure 100 may further include interconnection patterns 65 disposed on the interlayer insulating layers 90 and 95 and electrically connected to the contact structures 60, respectively.

The substrate 10 may include one of a silicon wafer, a single crystal silicon layer, or a silicon-on-insulator (SOI) layer. The isolation regions 15 may include an insulating material and may define an active region 17. The active region 17 may include a well region formed in the substrate 10. The well region may include a low concentration of N-type impurities or P-type impurities. The N-type impurity may include at least one of phosphorus (P) ions or arsenic (As) ions. The P-type impurity may include boron (B) ions or boron fluoride (BF₃) ions.

Referring to FIG. 1B, the gate structure 35 may include a gate stack 20 and a spacer structure 30. The gate stack 20 may include a gate dielectric layer 21, a lower gate electrode 22, a middle gate electrode 23, a gate barrier layer 24, an upper gate electrode 25, and a gate capping layer 26 disposed in the recited order over the substrate 10. The spacer structure 30 may include a first spacer 31, a second spacer 32, and a third spacer 33. The gate dielectric layer 21 may be directly formed on the active region 17 of the substrate 10. The gate dielectric layer 21 may include single insulating layer or multiple insulating layers. In an embodiment, the gate dielectric layer 21 may include an interfacial dielectric layer and a high-k dielectric layer. The interfacial dielectric material layer may include at least one of a silicon oxide (SiO₂) layer, a silicon nitride (SiN) layer, or a silicon oxy-nitride (SiON) layer. For example, the interfacial dielectric material layer may include a silicon oxide (SiON) layer including about 10 to 30% of nitrogen (N). The high-k dielectric material layer may include at least one of a hafnium oxide (HfO) layer, a hafnium oxy-nitride (HfON) layer, a zirconium oxide (ZrO) layer, a zirconium oxy-nitride (ZrON) layer, a zirconium hafnium oxide (ZrHfO) layer, zirconium hafnium oxy-nitride (ZrHfON) layer, or other metal oxide layers or metal oxy-nitride layers.

The lower gate electrode 22 may be positioned over the gate dielectric layer 21 and may include at least one of a metal layer or a metal nitride layer. In an embodiment, the lower gate electrode 22 may include a metal nitride layer including a dipole material. The dipole material may include lanthanum (La) and/or aluminum (Al). The metal nitride layer may include a titanium nitride (TiN) layer. For example, the lower gate electrode 22 may include at least one of a lanthanum-doped titanium nitride layer, a double layer of a lanthanum layer and a titanium nitride layer, an aluminum-doped titanium nitride layer, a double layer of an aluminum layer and a titanium nitride layer, a triple layer of an aluminum layer, a lanthanum layer, and a titanium nitride layer, and an aluminum-doped titanium nitride layer and/or a lanthanum-doped titanium nitride layer. In an embodiment, the lower gate electrode 22 may include at least one of lanthanum or aluminum, and at least one of a titanium layer or a titanium nitride layer. The lower gate electrode 22 can adjust (lower or raise) a threshold voltage by including the dipole material. For example, the lower gate electrode 22 may include lanthanum in an NMOS structure, or aluminum or lanthanum/aluminum in a PMOS structure.

The middle gate electrode 23 may be formed over the lower gate electrode 22 and may include an N-doped silicon layer. For example, the middle gate electrode 23 may include a polycrystalline silicon layer doped with phosphorus (P) or arsenic (As). The N-doped polycrystalline silicon layer may adjust a work function of the gate structure 35.

The gate barrier layer 24 may be formed over the middle gate electrode 23 and may prevent or block a movement of atoms between the middle gate electrode 23 and the upper gate electrode 25. The gate barrier layer 24 may include a titanium nitride (TiN) layer or a tantalum nitride (TaN) layer.

The upper gate electrode 25 may be formed over the gate barrier layer 24 and may include a conductor material having a lower resistance than the lower and middle gate electrodes 22 and 23. For example, the upper gate electrode 25 may include a metal such as tungsten (W).

The gate capping layer 26 may be formed over the upper gate electrode 25 and may protect the upper gate electrode 25 from etching damage and the like. The gate capping layer 26 may include a denser insulating layer than the lower interlayer insulating layer 90. For example, the gate capping layer 26 may include a silicon nitride layer. The gate capping layer 26 may be used as a hardmask layer to perform a patterning process.

The first spacers 31 may be formed on upper surfaces of both ends of the gate dielectric layer 21, and side surfaces of the lower gate electrode 22, the middle gate electrode 23, the gate barrier layer 24, the upper gate electrode 25, and the gate capping layer 26. The first spacers 31 may cover an upper surface of the gate insulation layer 21, and side surfaces of the lower gate electrode 22, the middle gate electrode 23, the gate barrier layer 24, the upper gate electrode 25, and the gate capping layer 26. Outer side surfaces of the first spacers 31 and both side ends of the gate dielectric layer 21 may be vertically aligned. The first spacers 31 may have an etch selectivity with respect to the gate dielectric layer 21. For example, the first spacers 31 may include silicon nitride.

The second spacers 32 may be disposed on a surface of the active region 17 of the substrate 10 and the outer side surfaces of the first spacers 31. The second spacers 32 may include silicon nitride. In an embodiment, the second spacers 32 may include silicon oxide. The third spacer 33 may be conformally disposed on the gate capping layer 26, the second spacers 32, the source/drain structure 40, and the isolation region 15. The third spacer 33 may include a silicon nitride layer.

The source/drain structure 40 may include a first dopant doped region 41 and a second dopant doped region 42 formed in the active region 17 of the substrate 10, a third dopant doped region 43 formed over the active region 17 of the substrate 10, and a fourth dopant doped region 44 formed in the third dopant doped region 43.

The first dopant doped region 41 may be disposed in the active region 17 to be adjacent to the surface (dotted line) of the active region 17 of the substrate 10. The first dopant doped region 41 may be formed to be shallower and thinner than the second dopant doped region 42. In a horizontal direction, one end of the first dopant doped region 41 may be vertically aligned with the outer side surface of the first spacer 31 and/or the ends of the gate dielectric layer 21.

The second dopant doped region 42 may be formed in the active region 17 of the substrate 10 below the first dopant doped region 41. The second dopant doped region 42 may be formed to be deeper and thicker than the first dopant doped region 41. In the horizontal direction, one end of the second dopant doped region 42 may be vertically aligned with the outer side surface of the second spacer 32. The first dopant doped region 41 is wider than the second dopant doped region 42 in the horizontal direction.

The third dopant doped region 43 may be formed to protrude from the surface of the active region 17 of the substrate 10. The third dopant doped region 43 may be a region epitaxially grown from the active region 17 of the substrate 10. That is, the third dopant doped region 43 may be an elevated dopant doped region. The third dopant doped region 43 may include one of a single crystal silicon layer, a SiGe layer, and a SiC layer.

The fourth dopant doped region 44 may be formed in the third dopant doped region 43. The fourth dopant doped region 44 may be disposed to be in contact with and overlap with a lower end portion of the contact structure 60.

The first to fourth dopant doped regions 41 to 44 may include at least one of phosphorus (P), arsenic (As), boron (B), or boron fluoride (BF₃). For example, in the NMOS structure, the first to fourth dopant doped regions 41 to 44 may include at least one of phosphorus (P) and arsenic (As), and in the PMOS structure, the first to fourth dopant doped regions 41 to 44 may include at least one of boron (B) and boron fluoride (BF₃).

The first dopant doped region 41 may include dopants doped with a first dopant concentration. For example, the first dopant concentration may be in a range of about 1E14/cm² to 5E15/cm². The dopants may include at least one of phosphorus (P), arsenic (As), boron (B), or boron fluoride (BF₃). The first dopant doped region 41 may further include carbon (C) doped with a first carbon doping concentration and/or germanium (Ge) doped with a first germanium concentration. The first carbon doping concentration and the first germanium doping concentration may be set in a range of about 1E14/cm² to 5E15/cm². In an embodiment, the first carbon doping concentration and the first germanium doping concentration may be set in a range of about 1E14/cm² to 5E14/cm². The first carbon doping concentration and the first germanium doping concentration may be equal to or less than the first dopant concentration. The first carbon doping concentration may be equal to or less than the first germanium doping concentration.

The second dopant doped region 42 may include dopants doped with a second dopant concentration. For example, the second dopant concentration may be set in a range of about 1E13/cm² to 5E15/cm². The second dopant concentration may be lower than the first dopant concentration. For example, the surface of the active region 17 may have a higher dopant concentration than the inside of the active region 17. The drain-induced bulk leakage current (DIBL) may be reduced by the second dopant doped region 42 with the lower dopant concentration.

The third dopant doped region 43 may include dopants doped with a third dopant concentration. The third dopant concentration may be set in a range of about 1E15/cm² to 2E16/cm². The third dopant concentration may be higher than the first dopant concentration and the second dopant concentration.

The fourth dopant doped region 44 may include dopants doped with a fourth dopant concentration. The fourth dopant concentration may be set in a range of about 1E21/cm² to 3E22/cm². The fourth dopant concentration may be set higher than the third dopant concentration. Accordingly, a contact resistance between the source/drain structure 40 and the contact structure 60 may be lowered.

The contact structure 60 may include a contact silicide layer 61, a contact barrier layer 62, and a contact plug 63. The contact silicide layer 61 may surround the lower end (also referred to as a bottom surface) of the contact barrier layer 62 in a bowl shape or “U” shape. The contact barrier layer 62 may conformally surround side surfaces and bottom surfaces of the contact plug 63. The bottom surface of the contact plug 63 may protrude downwardly to be rounded. The contact silicide layer 61 may include cobalt silicide (CoSi). The contact barrier layer 62 may include a titanium nitride layer. The cobalt silicide has lower resistivity than other silicides—for example tungsten silicide (WSi), titanium silicide (TiSi), or nickel silicide (NiSi)—and has more excellent adhesion to surrounding metal layers than the silicides. Therefore, in the embodiment, the contact silicide layer 61 may be the cobalt silicide (CoSi). The contact barrier layer 62 may include a barrier layer such as titanium nitride (TIN). The contact plug 63 may include a metal such as tungsten (W).

The contact structure 60 may vertically pass through the lower interlayer insulating layer 90 to be connected to the source/drain structure 40. For example, the lower ends of the contact structures 60 may protrude into the third dopant doped region 43 and/or the fourth dopant doped region 44 of the source/drain structure 40. That is, portions of upper portions of the third dopant doped region 43 and/or the fourth dopant doped region 44 may be recessed. The contact silicide layer 61 may be conformally disposed on the recessed portions of the third dopant doped region 43 and/or the fourth dopant doped region 44. The contact barrier layer 62 and the contact plug 63 may not be in direct contact with the third dopant doped region 43 and/or the fourth dopant doped region 44. That is, the contact silicide layer 61 may be disposed at an interface between the contact barrier layer 62 and the third dopant doped region 43 and/or at an interface between the contact barrier layer 63 and the fourth dopant doped region 44.

A horizontal width W1 of the contact structure 60 may be less than a horizontal width W2 of the third dopant doped region 43. That is, the horizontal width W1 of the contact silicide layer 61 may be less than the horizontal width W2 of the third dopant doped region 43. Accordingly, an offset between the contact silicide layer 61 and the contact plug 63 may be improved. Since the self-aligning process is not used, a contact between the contact silicide layer 61 of the contact structure 60 and the third and/or fourth source drain regions 43 and/or 44 may be formed to be spaced apart from the third gate spacer 33. Thus, trap sites and an electrical loss by the trap sites at an interface between the conductive elements 40 and 60 and the third gate spacer 33 can be reduced.

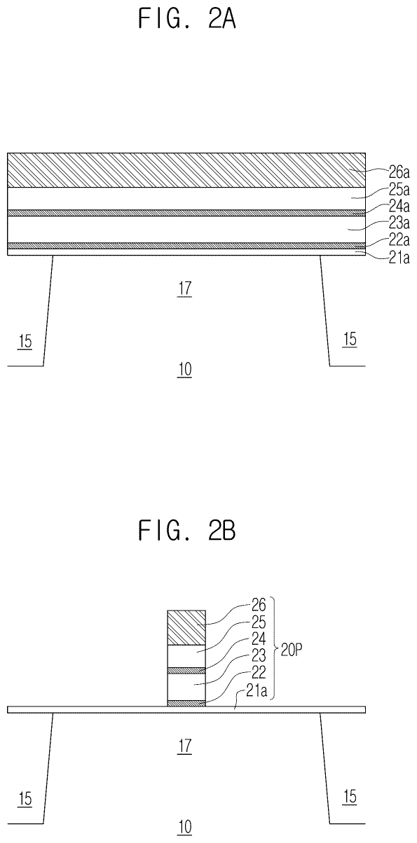

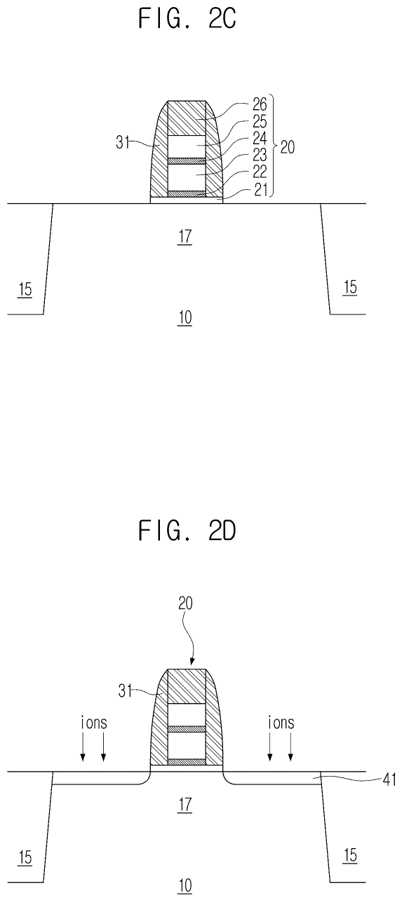

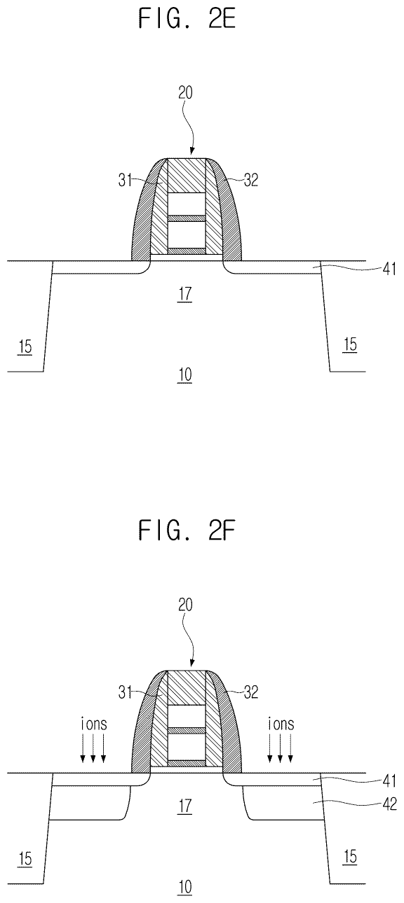

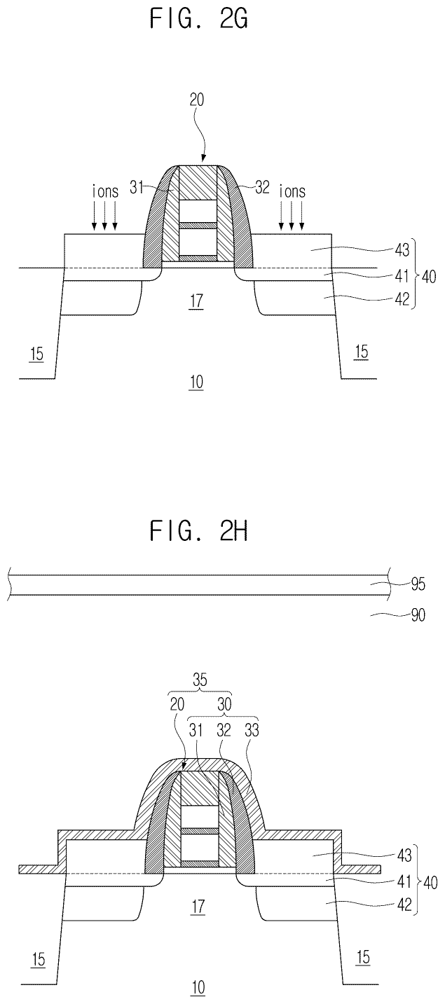

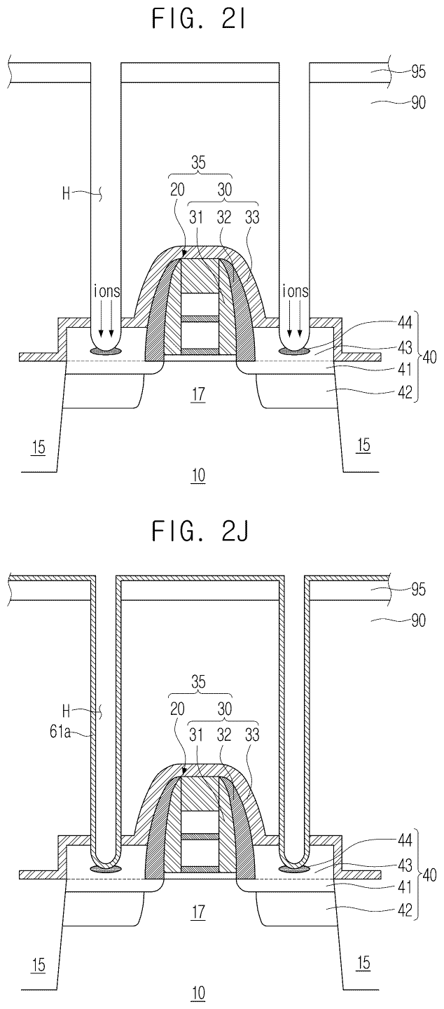

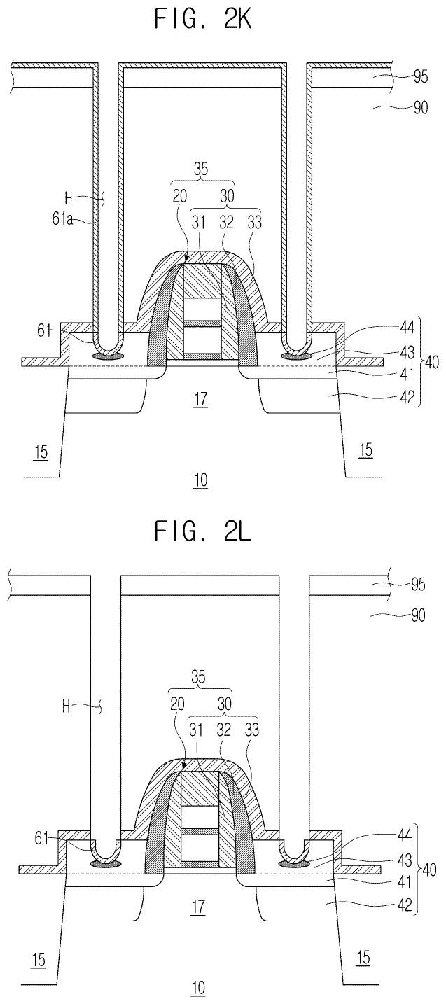

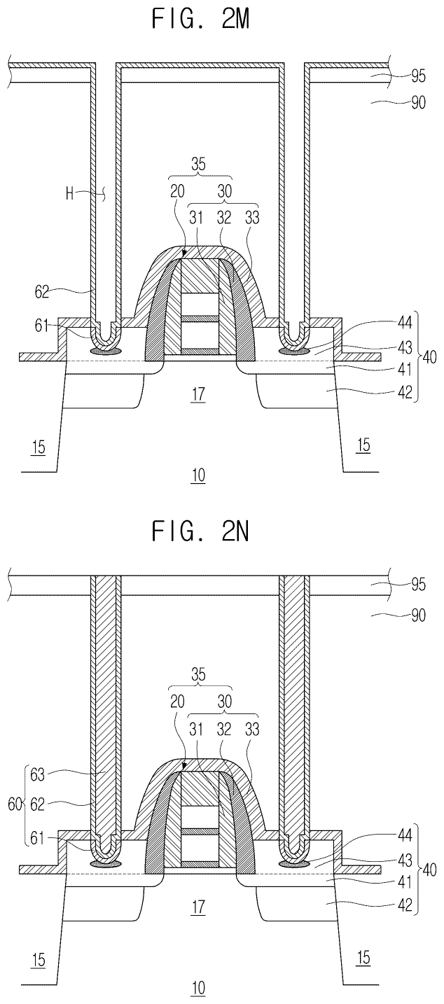

FIGS. 2A to 2N are views illustrating a method of forming a transistor structure of a semiconductor device according to an embodiment of the present disclosure.

Referring to FIG. 2A, the method of forming the transistor structure of the semiconductor device may include forming isolation regions 15 in a substrate 10, and sequentially forming a gate dielectric material layer 21a, a lower gate electrode material layer 22a, a middle gate electrode material layer 23a, a gate barrier material layer 24a, an upper gate electrode material layer 25a, and a gate capping material layer 26a over the substrate 10.

The substrate 10 may include a silicon wafer. In an embodiment, the substrate 10 may include a single crystalline silicon layer. The isolation regions 15 may be formed by forming trenches in the substrate 10 and filling the inside of the trenches with insulating materials. The active region 17 may be defined by the isolation regions 15.

Forming the gate dielectric material layer 21a may include forming an interfacial dielectric material layer and/or a high-k dielectric material layer on the substrate 10 by performing at least one of an oxidation process, a nitriding process, an oxynitride process, or a deposition process. Forming the interfacial dielectric material layer may include forming a silicon oxide (SiO₂) layer, a silicon nitride (SiN) layer, or a silicon oxynitride (SiON) layer by performing an oxidation process or a deposition process. The interfacial dielectric material layer may be selectively formed only on an exposed surface of the substrate 10. Forming the high-k dielectric material layer may include forming at least one of a hafnium oxide (HfO) layer, a hafnium oxide (HfON) layer, a zirconium oxide (ZrO) layer, a zirconium oxide (ZrON) layer, a zirconium hafnium oxide (ZrHfO) layer, a zirconium hafnium oxide (ZrHfON) layer, or other metal oxide layer by performing a deposition process.

Forming the lower gate electrode material layer 22a may include forming a metal nitride layer including a dipole material by performing a deposition process. The dipole material may include at least one of lanthanum (La) or aluminum (Al). For example, the metal nitride layer may include a titanium nitride (TiN) layer.

Forming the middle gate electrode material layer 23a may include forming an N-doped polycrystalline silicon layer by performing a deposition process.

Forming the gate barrier material layer 24a may include performing a deposition process to form one of a titanium nitride (TiN) layer, a tantalum nitride (TaN) layer, or a tungsten nitride (WN) layer.

Forming the upper gate electrode material layer 25a may include forming a metal material layer such as a tungsten (W) layer by performing a deposition process.

Forming the gate capping material layer 26a may include forming a material layer for an etching mask such as silicon nitride (SiN) by performing a deposition process.

Referring to FIG. 2B, the method may further include forming a mask pattern and forming a preliminary gate stack 20P by performing an etching process using the mask pattern as an etching mask. In the etching process, the gate capping material layer 26a, the upper gate electrode material layer 25a, the gate barrier material layer 24a, the middle gate electrode material layer 23a, and the lower gate electrode material layer 22a may be patterned and formed as a gate capping layer 26, an upper gate electrode 25, a gate barrier layer 24, a middle gate electrode 23, and a lower gate electrode 22. The gate dielectric material layer 21a may remain. The preliminary gate stack 20P may include the gate dielectric material layer 21a, the lower gate electrode 22, the middle gate electrode 23, the gate barrier layer 24, the upper gate electrode 25, and the gate capping layer 26. In another embodiment, the gate dielectric material layer 21a may also be patterned.

Referring to FIG. 2C, the method may further include forming a first spacer material layer by performing a deposition process, and etching the first spacer material layer to form a first spacer 31 and a gate dielectric layer 21. The gate dielectric material layer 21a may be patterned and formed to the gate dielectric layer 21. The preliminary gate stack 20P may thus be converted to a gate stack 20 which includes the gate dielectric layer 21, the lower gate electrode 22, the middle gate electrode 23, the gate barrier layer 24, the upper gate electrode 25, and the gate capping layer 26. The first spacer 31 may include a denser material than silicon oxide (SiO₂), e.g., silicon nitride (SiN). An outer side surface of the first spacer 31 and a lateral end portion of the gate dielectric layer 21 may be vertically aligned. That is, a lower surface of the first spacer 31 may be in contact with an outer portion (or peripheral portion) of the upper surface of the gate dielectric layer 21.

Referring to FIG. 2D, the method may further include forming a first dopant doped region 41 in the active region 17 of the exposed substrate 10 by performing a first dopant doping process. The first dopant doped region 41 may be formed to be shallow and close to the top surface of the active region 17. An inner end of the first dopant doped region 41 may be vertically aligned with the outer side surface of the first spacer 31. The first dopant doping process may include doping at least one of phosphorus (P) ions, arsenic (As) ions, boron (B) ions, or boron fluoride (BF₃) ions into a region close to the surface of the active region 17 with a first dopant concentration. In an embodiment, the first dopant doping process may further include doping carbon (C) ions into the active region 17 with a first carbon doping concentration. In an embodiment, the first dopant doping process may further include doping germanium (Ge) ions into the active region 17 with a first germanium doping concentration. Thus, the first dopant doped region 41 may include at least one of phosphorus (P) ions, arsenic (As) ions, boron (B) ions, or boron fluoride (BF₃) ions, carbon (C) ions, and germanium (Ge) ions. The first dopant concentration may be in a range of about 1E14/cm² to 5E15/cm². The first carbon doping concentration and/or the first germanium doping concentration may be equal to or less than the first dopant concentration. The first carbon doping concentration may be equal to or less than the first germanium doping concentration. The carbon (C) ions and the germanium (Ge) ions may adjust a lattice structure and vacancies of the active region 17 of the substrate 10. For example, carbon (C) ions and germanium (Ge) ions can control diffusions of phosphorus (P) ions, arsenic (As) ions, boron (B) ions, or boron fluoride (BF₃) ions.

In an embodiment, the method may further include forming a halo ion doped region to abut the first dopant doped region 41 in a horizontal direction in the active region 17 vertically aligned and overlapping with the first spacer 31. Forming the halo ion doped region may include performing a tilted ion doping process to obliquely dope ions having polarities opposite to the doped ions in the first dopant doped region 31.

Referring to FIG. 2E, the method may further include forming a second spacer material layer and performing an etching process such as an etch-back process to form a second spacer 32. For example, the second spacer 32 may include silicon oxide or silicon nitride. The second spacer 32 may be formed on the outer side surface of the first spacer 31 and to be in contact with a side end portion of the gate dielectric layer 21. The second spacer 32 may be in contact with the exposed active region 17 and more specifically with the first dopant doped region 41.

Referring to FIG. 2F, the method may further include doping dopants into the exposed active region 17 by performing a second dopant doping process and performing a heat treatment process to form a second dopant doped region 42. The second dopant doping process may include doping at least one of phosphorus (P) ions, arsenic (As) ions, boron (B) ions, or boron fluoride (BF₃) ions into a position deeper than the first dopant doped region 41 in the active region 17 with a second dopant concentration. Accordingly, the second dopant doped region 42 may be formed at a position deeper than the first dopant doped region 41 in the active region 17. The second dopant concentration may be set in a range of about 1E13/cm² to 5E15/cm². The second dopant concentration may be equal to or less than the first dopant concentration. An inner end of the second dopant doped region 42 may be vertically aligned with an outer side surface of the second spacer 32.

In an embodiment, the second dopant doping process may further include doping carbon ions and/or germanium ions into a shallow region within the active region 17, that is, the region is close to the surface of the active region 17. The carbon ions and/or germanium ions in the shallow region close to the surface of the active region 17 can prevent and control the diffusions of phosphorus (P) ions, arsenic (As) ions, boron (B) ions, and boron fluoride (BF₃) ions.

The heat treatment process may include a rapid thermal annealing (RTA) process. The RTA process may include heating the substrate 10 at a temperature of about 1,000° C. to 1,200° C. for about some seconds, e.g., 1 to 2 seconds. By the heat treatment process, the doped ions may diffuse. By performing the heat treatment process, the dopants in the first dopant doped region 41 and/or the second dopant doped region 42 may diffuse.

Referring to FIG. 2G, the method may further include forming a third dopant doped region 43 by performing an epitaxial growth process and a third dopant doping process. The third dopant doped region 43 may upwardly protrude from the surface of the substrate 10. For example, the third dopant doped region 43 may be an elevated dopant doped region. The third dopant doping process may include doping at least one of phosphorus (P) ions, arsenic (As) ions, boron (B) ions, or boron fluoride (BF₃) ions into the third dopant doped region 43 with a third dopant concentration. The third dopant concentration may be higher than the first dopant concentration and/or the second dopant concentration. For example, the third dopant concentration may be set in a range of about 5E15/cm² to about 2E16/cm². In an embodiment, the third dopant doping process may further include doping carbon ions and/or germanium ions into the third dopant doped region 43. The carbon ions and/or germanium ions may be doped into a lower region of the third dopant doped region 43. The carbon ions and/or germanium ions doped close to the surface of the active region 17 in the first dopant doped region 41 and the carbon ions and/or germanium ions doped in the lower region of the third dopant doped region 43 in the third dopant doping process may prevent and control the diffusion of the dopants-phosphorus (P) ions, arsenic (As) ions, boron (B) ions, and boron fluoride (BF₃) ions. In a subsequent process, the dopants doped with a high dopant concentration may be prevented and controlled from diffusing into the active region 17 by the carbon ion and/or germanium ions.

Referring to FIG. 2H, the method may further include forming a third spacer 33, and forming a lower interlayer insulating layer 90 and an upper interlayer insulating layer 95 by performing deposition processes. The third spacer 33 may be formed to conformally cover the entire top surface of the structure of FIG. 2G. For example, the third spacer 33 may be conformally formed on an upper and side surfaces of the gate stack 20, a surface of the third dopant doped region 43, and a surface of the isolation regions 15. The third spacer 33 may include silicon nitride (SiN). A gate structure 35 including the gate stack 20 and the third spacer 33 may be formed. The lower interlayer insulating layer 90 may be formed sufficiently thick to cover the gate structure 40. The lower interlayer insulating layer 90 may include silicon oxide (SiO₂) layer. An upper surface of the lower interlayer insulating layer 90 may be flat. The upper interlayer insulating layer 95 may be conformally formed over the lower interlayer insulating layer 90. The upper interlayer insulating layer 95 may include an insulating material denser than the lower interlayer insulating layer 90. For example, the upper interlayer insulating layer 95 may include silicon nitride (SiN) layer. In an embodiment, the lower interlayer insulating layer 90 may include multiple insulating layers. In an embodiment, the upper interlayer insulating layer 95 may be omitted.

Referring to FIG. 2I, the method may further include forming a contact hole H penetrating the lower interlayer insulating layer 90 and the third spacer 33 to expose an inside of the third dopant doped region 43 by performing a hole forming process, and doping at least one of phosphorus (P) ions, arsenic (As) ions, boron (B) ions, or boron (BF₃) ions into the third dopant doped region 43 exposed inside the contact hole H with a fourth dopant concentration. A lower end of the contact hole H may be located inside the third dopant doped region 43. That is, a surface of the third dopant doped region 43 may be recessed by the contact hole H. In the fourth dopant doping process, at least one of phosphorus (P) ions, arsenic (As) ions, boron (B) ions, or boron fluoride (BF₃) ions may be doped close to the surface of the exposed active region 17. For example, the one of phosphorus (P) ions, arsenic (As) ions, boron (B) ions, or boron fluoride (BF₃) ions may be doped under a bottom surface of the contact hole H. A fourth dopant doped region 44 may be formed in the third dopant doped region 43 below the bottom surface of the contact hole H. In an embodiment, the fourth dopant doping process may further include doping carbon ions and/or germanium ions under the doped phosphorus (P) ions, arsenic (As) ions, boron (B) ions, or boron fluoride (BF₃) ions. The carbon ions and/or germanium ions may be doped to surround a lower portion of a region into which phosphorus (P) ions, arsenic (As) ions, boron (B) ions, or boron fluoride (BF₃) ions are doped.

Referring to FIG. 2J, the method may further include forming a metal layer 61a for forming silicide on inner walls and the bottom surface of the contact hole H by performing a deposition process. The metal layer 60a for forming silicide may be conformally formed. In an embodiment, the metal layer 61a for forming silicide may be formed to fill the lower end of the contact hole H. The metal layer 61a for silicide may include cobalt (Co).

Referring to FIG. 2K, the method may further include forming a contact silicide layer 61 by subjecting a portion of the metal layer 61a for silicide on the bottom surface of the contact hole H to a silicidation process. The contact silicide layer 61 may include cobalt silicide (CoSi). The contact silicide layer 61 may be conformally formed on the lower end of the contact hole H. For example, the contact silicide layer 61 may be formed on the surface of the third dopant doped region 43 exposed within the contact hole H. If the contact silicide layer 61 is overall conformally formed on the third dopant doped region 43, that is, when the self-aligned silicide process is performed, the substrate 10 exposed to high heat for a long time. Accordingly, dopants may excessively diffuse. That is, it is difficult to obtain an appropriate doping profile, and resistance may be increased.

Referring to FIG. 2L, the method may further include removing the remaining metal layer 61a which was added for forming the silicide layer except for the contact silicide layer 61 inside the third dopant doped region 43 by performing a removal process.

Referring to FIG. 2M, the method may further include conformally forming a contact barrier layer 62 on the inner walls of the contact hole H and the contact silicide layer 61 by performing a deposition process. The contact barrier layer 62 may include, for example, titanium nitride (TiN) layer.

Referring to FIG. 2N, the method may further include forming a contact plug 63 to fill an inside of the contact hole H on the contact barrier layer 62 by performing a hole filling process. The contact barrier layer 62 may conformally surround a bottom surface and side surfaces of the contact plug 63. The method may further include co-planarizing an upper surface of the upper interlayer insulating layer 95, an upper surface of the contact barrier layer 62, and an upper surface of the contact plug 63 by performing a chemical mechanical polishing (CMP) process.

Hereafter, referring to FIG. 1A, the method may further include forming interconnection patterns 65 on the contact structure 60 by performing an interconnection forming process. The interconnection patterns 65 may have a line shape extending horizontally or a square pad shape.

According to the embodiment of the present disclosure, a contact structure can be formed under a process condition of a low heat treatment temperature and a short heat treatment time. Accordingly, the contact structure can have a better dopant profile and a lower contact resistance than a contact structure formed under a high heat treatment temperature and a long heat treatment time.

While the embodiments of the present disclosure have been described with respect to specific embodiments, it will be apparent to those skilled in the art that various changes and modifications may be made without departing from the technical concepts and scope of the present disclosure as defined in the following claims. Furthermore, the embodiments may be combined to form additional embodiments.

What is claimed is:

1. A semiconductor device comprising:
a gate structure over a substrate;
a source/drain structure in the substrate; and
a contact structure over the source/drain structure,
wherein the source/drain structure includes:
a first dopant doped region having first dopants doped with a first doping concentration in the substrate;
a second dopant doped region having second dopants doped with a second doping concentration under the first dopant doped region in the substrate; and
a third dopant doped region protruding from the substrate and having third dopants doped with a third doping concentration,
wherein the first dopant concentration is higher than the second dopant concentration, and
wherein the third dopant concentration is higher than the first dopant concentration.

2. The semiconductor device of claim 1, further comprising:
a fourth dopant doped region within the third dopant doped region, and
wherein the fourth dopant doping region is adjacent to and is overlapping with a lower end of the contact structure.

3. The semiconductor device of claim 2,
wherein the fourth dopant doped region includes fourth dopants doped with a fourth dopant concentration,
wherein the fourth dopant concentration is higher than the third dopant concentration.

4. The semiconductor device of claim 1,
wherein the first dopant doped region is formed to be shallower and thinner than the second and third dopant doped regions to be adjacent to a surface of the substrate.

5. The semiconductor device of claim 1,
wherein the second dopant doped region is formed deeper and thicker than the first dopant doped region, and
wherein the first dopant doped region is wider than the second dopant doped region in a horizontal direction.

6. The semiconductor device of claim 1,
wherein the third dopant doped region includes an epitaxial growth layer.

7. The semiconductor device of claim 1,
wherein the contact structure vertically passes through an interlayer insulating layer covering the gate structure and the source/drain structure and downwardly protrudes into the third dopant doped region.

8. The semiconductor device of claim 2,
wherein the contact structure includes:
a contact plug;
a contact barrier layer conformally surrounding side surfaces and a bottom surface of the contact plug; and
a contact silicide layer surrounding a bottom surface of the contact barrier layer.

9. The semiconductor device of claim 8,
wherein the contact barrier layer includes a titanium nitride layer, and
wherein the contact silicide layer includes a cobalt silicide layer.

10. The semiconductor device of claim 8,
wherein a horizontal width of the contact silicide layer is less than a horizontal width of the third dopant doped region.

11. The semiconductor device of claim 1,
wherein the gate structure includes:
a gate stack;
a first spacer on a sidewall of the gate stack;
a second spacer on a sidewall of the first spacer; and
a third spacer conformally formed on a sidewall and an upper surface of the second spacer, and over a surface of the third source/drain region.

12. The semiconductor device of claim 11,
wherein the gate stack includes:
a gate dielectric layer;
a gate electrode over the gate dielectric layer; and
a gate capping layer over the gate electrode,
wherein the first spacer is formed on a portion of an upper surface of the gate dielectric layer and a side surface of the gate electrode.

13. The semiconductor device of claim 12,
wherein the gate dielectric layer includes:
an interfacial dielectric layer directly formed on the substrate; and
a high-k dielectric layer over the interfacial dielectric layer.

14. The semiconductor device of claim 12,
wherein the gate electrode includes:
a lower gate electrode and an upper gate electrode,
wherein the lower gate electrode includes a titanium nitride layer including at least one of lanthanum or aluminum, and
wherein the upper gate electrode includes a metal.

15. The semiconductor device of claim 14,
wherein the gate electrode further includes a middle gate electrode between the lower gate electrode and the upper gate electrode, and
wherein the middle gate electrode includes N-doped polycrystalline silicon.

16. The semiconductor device of claim 15,
wherein the gate electrode further includes a gate barrier layer between the middle gate electrode and the upper gate electrode, and
wherein the gate barrier layer includes a titanium nitride layer.

17. A semiconductor device comprising:
a gate structure over a substrate;
a source/drain structure in the substrate; and
a contact structure over the source/drain region,
wherein the source/drain structure includes:
a lower concentration dopant doped region including dopants doped with a low concentration formed in the substrate;
a meddle concentration dopant doped region including the dopant doped with a middle concentration protruding from a surface of the substrate; and
a high concentration dopant doped region including the dopants doped with a high concentration formed within the middle concentration dopant doped region, and
wherein the high concentration dopant doped region is adjacent to a lower end of the contact structure.

18. The semiconductor device of claim 17,
wherein the contact structure downwardly protrudes into the middle concentration dopant doped region,
wherein the contact structure includes a contact plug, a contact barrier layer conformally surrounding side surfaces and a bottom surface of the contact plug, and a contact silicide layer surrounding the bottom surface of the contact barrier layer, and
wherein a horizontal width of the contact silicide layer is less than a horizontal width of the middle concentration dopant doped region.

19. The semiconductor device of claim 17,
wherein the middle concentration dopant doped region includes an epitaxial growth layer.

20. The semiconductor device of claim 17,
wherein the low concentration dopant doped region further includes carbon and germanium.

21. A method of manufacturing a semiconductor device comprising:
defining an active region in a substrate;
forming a gate stack over the active region;
forming a first spacer on a side surface of the gate stack;
forming a first dopant doped region in the active region exposed by the first spacer;
forming a second spacer on a side surface of the first spacer;
forming a second dopant doped region under the first dopant doped region in the active region exposed by the second spacer;
forming a third dopant doped region over the first dopant doped region;
forming a third spacer covering an upper surface of the gate stack, an outer side surface of the second spacer, and an upper surface of the third dopant doped region;
forming an interlayer insulating layer covering the gate stack and the third spacer;
forming a contact hole penetrating the interlayer insulating layer and the third spacer to expose the third dopant doped region;
forming a fourth dopant doped region in the third dopant doped region exposed in the contact hole; and
forming a contact plug in the contact hole to form a contact structure.

22. The method of claim 21,
wherein forming the gate stack includes:
forming a gate dielectric layer over the active region;
forming a gate electrode over the gate dielectric layer;
forming a gate capping layer over the gate electrode,
wherein the first spacer is formed on a portion of an upper surface of the gate dielectric layer, a side surface of the gate electrode, and a side surface of the gate capping layer.

23. The method of claim 22,
wherein the second spacer is in contact with a side surface of the gate dielectric layer.

24. The method of claim 21,
wherein forming the first dopant doped region includes performing a dopant doping process to dope at least one of phosphorus ions, arsenic ions, boron ions, or boron fluoride ions into the active region,
wherein the first dopant doped region is formed to be shallower and thinner than the second dopant doped region to be close to a surface of the active region.

25. The method of claim 21,
wherein forming the second source/drain region includes performing a dopant doped process to dope at least one of phosphorus, arsenic, boron, or boron fluoride into the active region, and
wherein the second source/drain region is formed under the first source/drain region to be deeper and thicker than the first source/drain region.

26. The method of claim 21,
wherein forming the third dopant doped region includes:
forming an epitaxial growth layer over the active region by performing an epitaxial growth process; and
doping at least one of phosphorus ions, arsenic ions, boron ions, and boron fluoride ions into the epitaxial growth layer by performing a dopant doping process.

27. The method of claim 21,
wherein the first dopant doped region has dopants doped with a first dopant concentration,
wherein the second dopant doped region has the dopants doped with a second dopant concentration,
wherein the third dopant doped region has the dopants doped with a third dopant concentration,
wherein the fourth dopant doped region has the dopants doped with a fourth dopant concentration,
wherein the third dopant concentration is higher than the first dopant concentration and the second dopant concentration, and
wherein the fourth dopant concentration is higher than the third dopant concentration.

28. The method of claim 21,
herein the first dopant doped region includes carbon ions, germanium ions, and at least one of phosphorus ions, arsenic ions, boron ions, and boron fluoride ions.

29. A method of manufacturing a semiconductor device comprising:
defining an active region in the substrate;
forming a gate stack over the active region;
forming a low concentration dopant doped region in the active region;
forming a middle concentration dopant doped region over the active region;
forming a high concentration dopant doped region in the middle concentration dopant doped region; and
forming a contact structure in contact with the high concentration dopant doped region.

30. The method of claim 29,
wherein forming the low concentration dopant doped region includes doping carbon ions, germanium ions, and at least one of phosphorus ions, arsenic ions, boron ions, or boron fluoride ions.

31. The method of claim 29,
wherein forming the middle concentration dopant doped region includes:
forming an elevated region by performing an epitaxial growth process, and
doping dopant into the elevated region by performing a dopant doping process.

32. The method of claim 29,
wherein forming the high concentration dopant doped region includes:
forming a contact hole to recess a portion of a surface of the middle concentration dopant doped region, and
doping dopants into the middle concentration dopant doped region exposed at a bottom of the contact hole.

33. The method of claim 29,
wherein forming the contact structure includes:
forming a contact hole to recess a portion of a surface of the middle concentration dopant doped region, and
forming a contact silicide layer over the middle concentration dopant region exposed at a bottom of the contact hole.

34. The method of claim 33, further comprising:
wherein forming the contact structure includes:
forming a contact barrier layer over the contact silicide layer, and
forming a contact plug over the contact barrier layer,
wherein the contact barrier layer includes a silicon nitride layer, and
wherein the contact plug includes a metal.

35. The method of claim 29,
wherein forming the gate structure includes:
forming a gate stack including a gate dielectric layer, a gate electrode, and a gate capping layer over the active region, and
forming a gate spacer on a side of the gate stack.
